(19) United States
(12) Patent Application Publication
(10) Pub. No.: US 2026/0033297 A1
(43) Pub. Date: Jan. 29, 2026

(54) SEMICONDUCTOR DEVICE

(71) Applicant: Samsung Electronics Co., Ltd., Suwon-si (KR)

(72) Inventors: Junghyun ROH, Suwon-si (KR); Hwanseok KU, Suwon-si (KR)

(73) Assignee: Samsung Electronics Co., Ltd., Suwon-si (KR)

(21) Appl. No.: 19/269,525

(22) Filed: Jul. 15, 2025

(30) Foreign Application Priority Data
Jul. 23, 2024 (KR) 10-2024-0097517

(51) Int. Cl. H01L 21/66; H01L 23/00; H01L 25/065; H01L 25/18; H10B 80/00

(52) U.S. Cl. CPC H01L 22/32; H01L 24/08; H01L 25/0657; H01L 25/18; H10B 80/00; H01L 2224/08145; H01L 2225/06596; H01L 2924/1431; H01L 2924/14511

(57) ABSTRACT

A semiconductor device includes a semiconductor die including a central region and an outer region surrounding the central region, a semiconductor integrated circuit across a plurality of sub regions of the central region, an outer crack detection structure in the outer region along an edge of the outer region and divided into a plurality of outer conduction segments, a central crack detection structure crossing the central region and divided into a plurality of central conduction segments, a plurality of first path selection circuits each connected to at least one of the plurality of outer conduction segments and at least one of the plurality of central conduction segments, and a second path selection circuit connected between the plurality of central conduction segments.

### CROSS-REFERENCE TO RELATED APPLICATION

This application claims benefit of and priority under 35 U.S.C. § 119 to Korean Patent Application No. 10-2024-0097517, filed on Jul. 23, 2024, in the Korean Intellectual Property Office, the disclosure of which is incorporated by reference herein in its entirety.

### BACKGROUND

The inventive concepts relate to semiconductor devices, and more particularly, to semiconductor devices including a crack detection structure.

In general, integrated circuits are formed in a repetitive pattern on a wafer of semiconductor material. The wafer is cut into a large number of individual semiconductor dies, and each of the semiconductor dies is packaged into a semiconductor chip. During the cutting and packaging processes, cracks may occur in semiconductor dies. It is required to prevent or reduce in likelihood defective products from being released by more precisely detecting cracks.

### SUMMARY

The inventive concepts provide semiconductor devices capable of detecting a location, for example an exact location, of a crack and/or increase the ability to sense crack penetration in various paths. The inventive concepts may also provide semiconductor devices capable of detecting a bonding failure in a contact region between wafers.

The inventive concepts are not limited to those mentioned above and will be clearly understood by those skilled in the art from the descriptions below.

According to some aspects of the inventive concepts, there is provided a semiconductor device including a semiconductor die including a central region and an outer region surrounding the central region, a semiconductor integrated circuit across a plurality of sub regions of the central region, an outer crack detection structure in the outer region along an edge of the outer region and divided into a plurality of outer conduction segments, a central crack detection structure crossing the central region and divided into a plurality of central conduction segments, a plurality of first path selection circuits each connected to at least one of the plurality of outer conduction segments and at least one of the plurality of central conduction segments, and a second path selection circuit connected between the plurality of central conduction segments.

According to other aspects of the inventive concepts, there is provided a semiconductor device including a semiconductor die including a central region and an outer region surrounding the central region, a semiconductor integrated circuit across a plurality of sub regions of the central region, an outer crack detection structure in the outer region along an edge of the outer region and including a plurality of outer conduction segments, a central crack detection structure crossing the central region in the central region and including a plurality of central conduction segments, a first path selection circuit connected between the plurality of outer conduction segments and between the plurality of central conduction segments, and a second path selection circuit connected between the plurality of central conduction segments.

According to a further aspects of the inventive concepts, there is provided a semiconductor device including a semiconductor die including a central region and an outer region surrounding the central region, a semiconductor integrated circuit across a plurality of sub regions of the central region, an outer crack detection structure in the outer region along an edge of the outer region and divided into a plurality of outer conduction segments, an inner crack detection structure in the central region along the edge of the outer region and divided into a plurality of inner conduction segments, a central crack detection structure crossing the central region and divided into a plurality of central conduction segments, and a plurality of first path selection circuits each connected to at least one of the plurality of outer conduction segments, at least one of the plurality of inner conduction segments, and at least one of the plurality of central conduction segments.

### BRIEF DESCRIPTION OF THE DRAWINGS

Some example embodiments will be more clearly understood from the following detailed description taken in conjunction with the accompanying drawings in which:

FIG. 1 is a plan view illustrating the layout of a semiconductor device according to some example embodiments;

FIG. 2 is a plan view illustrating the layout of a semiconductor device according to some example embodiments;

FIG. 3 is a block diagram of a test system according to some example embodiments;

FIGS. 4 to 6 are plan views illustrating the layout of a semiconductor device according to some example embodiments and show the flows of test signals for crack detection of the semiconductor device;

FIGS. 7A to 7D are plan views illustrating the layout of a semiconductor device according to some example embodiments and show the flows of test signals for crack detection of the semiconductor device;

FIG. 8 is a plan view illustrating the layout of a semiconductor device according to some example embodiments;

FIGS. 9A and 9B are plan views illustrating the layout of a semiconductor device according to some example embodiments and show the flows of test signals for crack detection of the semiconductor device;

FIG. 10 is a plan view illustrating the layout of a semiconductor device according to some example embodiments and shows the flow of a test signal for crack detection of the semiconductor device;

FIGS. 11A and 11B are plan views illustrating the layout of a semiconductor device according to some example embodiments and show the flows of test signals for crack detection of the semiconductor device;

FIG. 12 is a plan view illustrating the layout of a semiconductor device according to some example embodiments;

FIG. 13 is a perspective view illustrating an outer crack detection structure according to some example embodiments;

FIG. 14 is a block diagram of a semiconductor device according to some example embodiments;

FIG. 15 is a schematic plan view of a semiconductor device according to some example embodiments;

FIG. 16 is a perspective view illustrating an example of a semiconductor die according to some example embodiments;

FIG. 17 is a cross-sectional view of partial regions of a peripheral circuit structure and a cell array structure of a semiconductor device, according to some example embodiments; and

FIG. 18 is a cross-sectional view illustrating an inner crack detection structure according to embodiments.

### DETAILED DESCRIPTION

Hereinafter, some example embodiments are described in detail with reference to the accompanying drawings. In the drawing, like reference characters denote like elements, and redundant descriptions thereof will be omitted.

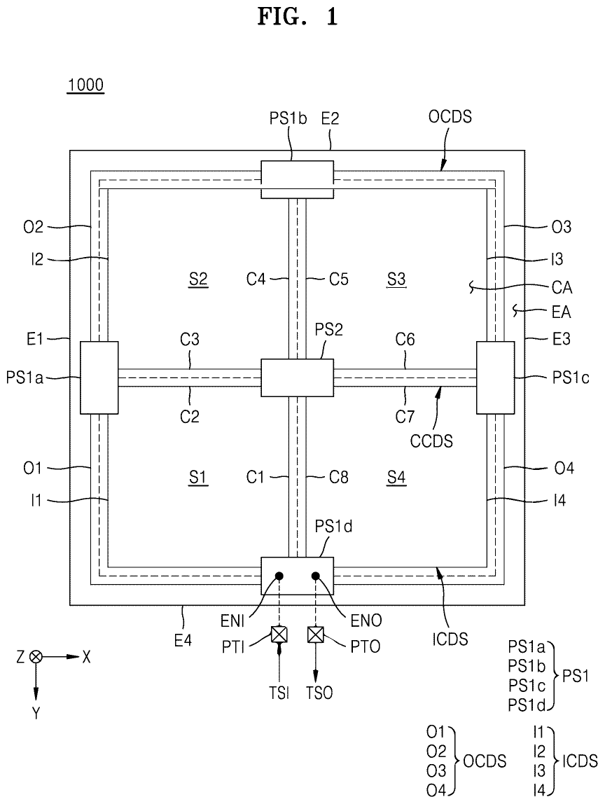

Referring to FIG. 1, a semiconductor device 1000 may include at least one semiconductor die. The semiconductor die may include a central region CA and an outer region EA surrounding the central region CA.

The central region CA may include a plurality of sub regions. In some example embodiments, the sub regions may include a first sub region S1, a second sub region S2, a third sub region S3, and a fourth sub region S4. Various semiconductor integrated circuits may be formed in the sub regions (e.g., S1, S2, S3, and S4) according to the type of the semiconductor device 1000. For example, the semiconductor device 1000 may be a non-volatile memory device. In this case, a memory integrated circuit may be formed in the central region CA.

An outer crack detection structure OCDS may be in the outer region EA. The outer crack detection structure OCDS may detect the presence and/or location of a crack in the outer region EA. For example, a crack that occurs during a process, such as wafer cutting, and penetrates into a chip may be detected.

In a plan view, the outer crack detection structure OCDS may extend along edges (e.g., E1, E2, E3, and E4) of the outer region EA. The outer crack detection structure OCDS may surround the central region CA.

The outer crack detection structure OCDS may include a plurality of outer conduction segments. The outer crack detection structure OCDS may be divided into a plurality of outer conduction segments. The outer conduction segments may be connected to each other by a plurality of first path selection circuits PS1.

In some example embodiments, the outer conduction segments of the outer crack detection structure OCDS may include first to fourth outer conduction segments O1, O2, O3, and O4. The outer crack detection structure OCDS may be divided into the first to fourth outer conduction segments O1, O2, O3, and O4. The first to fourth outer conduction segments O1, O2, O3, and O4 may be electrically connected to one another through the first path selection circuits PS1, thereby forming a conduction loop having an input end node ENI and an output end node ENO. Accordingly, the outer crack detection structure OCDS may have an annular shape.

In some example embodiments, a plurality of outer conduction segments of the outer crack detection structure OCDS may be arranged in correspondence to a plurality of sub regions of the central region CA. For example, the first outer conduction segment O1 may surround a portion of the edge of the first sub region S1, the second outer conduction segment O2 may surround a portion of the edge of the second sub region S2, the third outer conduction segment O3 may surround a portion of the edge of the third sub region S3, and the fourth outer conduction segment O4 may surround a portion of the edge of the fourth sub region S4.

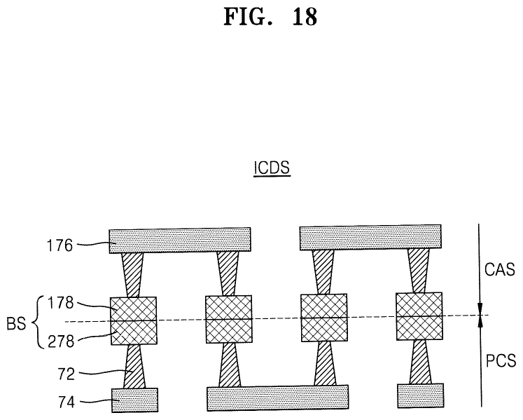

An inner crack detection structure ICDS may be in the central region CA. In a plan view, the inner crack detection structure ICDS may extend along the edge of the outer region EA. The inner crack detection structure ICDS may detect the presence and/or location of a crack in the central region CA. In some example embodiments, the inner crack detection structure ICDS may detect a bonding failure between wafers. This is described below with reference to FIG. 18.

The inner crack detection structure ICDS may include a plurality of inner conduction segments. The inner crack detection structure ICDS may be divided into a plurality of inner conduction segments. The inner conduction segments may be connected to each other by the first path selection circuits PS1.

In some example embodiments, the inner conduction segments of the inner crack detection structure ICDS may include first to fourth inner conduction segments I1, I2, I3, and I4. The inner crack detection structure ICDS may be divided into the first to fourth inner conduction segments I1, I2, I3, and I4. The first to fourth inner conduction segments I1, I2, I3, and I4 may be electrically connected to one another through the first path selection circuits PS1, thereby forming a conduction loop having the input end node ENI and the output end node ENO. Accordingly, the inner crack detection structure ICDS may have an annular shape.

In some example embodiments, a plurality of inner conduction segments of the inner crack detection structure ICDS may be respectively arranged in a plurality of sub regions of the central region CA. For example, the first inner conduction segment I1 may be arranged in the first sub region S1, the second inner conduction segment I2 may be arranged in the second sub region S2, the third inner conduction segment I3 may be arranged in the third sub region S3, and the fourth inner conduction segment I4 may be arranged in the fourth sub region S4.

In some example embodiments, a plurality of inner conduction segments of the inner crack detection structure ICDS may be arranged in correspondence to a plurality of outer conduction segments of the outer crack detection structure OCDS. For example, in a plan view, the first inner conduction segment I1 may extend along the first outer conduction segment O1, the second inner conduction segment I2 may extend along the second outer conduction segment O2, the third inner conduction segment I3 may extend along the third outer conduction segment O3, and the fourth inner conduction segment I4 may extend along the fourth outer conduction segment O4.

A central crack detection structure CCDS may be in the central region CA. In a plan view, the central crack detection structure CCDS may cross the central region CA. The central crack detection structure CCDS may detect the presence and/or location of a crack in the central region CA. In some example embodiments, the central crack detection structure CCDS may detect a bonding failure between wafers.

The central crack detection structure CCDS may include a plurality of central conduction segments. The central crack detection structure CCDS may be divided into a plurality of central conduction segments. The central conduction segments may be connected to each other by the first path selection circuits PS1 and a second path selection circuit PS2 described below.

In some example embodiments, a plurality of central conduction segments of the central crack detection structure CCDS may include first to eighth central conduction segments C1, C2, C3, C4, C5, C6, C7, and C8. The central crack detection structure CCDS may be divided into the first to eighth central conduction segments C1 to C8. The first to eighth central conduction segments C1 to C8 may be electrically connected to one another through the first path selection circuits PS1 and the second path selection circuit PS2, thereby forming a conduction loop having the input end node ENI and the output end node ENO.

In some example embodiments, a plurality of central conduction segments of the central crack detection structure CCDS may be arranged in a plurality of sub regions (e.g., S1 to S4) of the central region CA. For example, the first central conduction segment C1 and the second central conduction segment C2 may be arranged in the first sub region S1, the third central conduction segment C3 and the fourth central conduction segment C4 may be arranged in the second sub region S2, the fifth central conduction segment C5 and the sixth central conduction segment C6 may be arranged in the third sub region S3, and the seventh central conduction segment C7 and the eighth central conduction segment C8 may be arranged in the fourth sub region S4.

In some example embodiments, some of a plurality of central conduction segments of the central crack detection structure CCDS may cross the central region CA in a first direction (an X direction), and the other central conduction segments thereof may cross the central region CA in a second direction (a Y direction) that is perpendicular to the first direction (the X direction).

In some example embodiments, two central conduction segments among a plurality of central conduction segments of the central crack detection structure CCDS may be adjacent to each other. For example, the first and eighth central conduction segments C1 and C8 may be adjacent to each other, the second and third central conduction segments C2 and C3 may be adjacent to each other, the fourth and fifth central conduction segments C4 and C5 may be adjacent to each other, and the sixth and seventh central conduction segments C6 and C7 may be adjacent to each other.

Referring to FIG. 1, according to some example embodiments, the semiconductor device 1000 may include the plurality of first path selection circuits PS1. The first path selection circuits PS1 may be connected to the outer crack detection structure OCDS and may control electrical connection of the outer crack detection structure OCDS. The first path selection circuits PS1 may be connected to the inner crack detection structure ICDS and may control electrical connection of the inner crack detection structure ICDS. The first path selection circuits PS1 may be connected to the central crack detection structure CCDS and may control electrical connection of the central crack detection structure CCDS. The first path selection circuits PS1 may control electrical connection among the outer crack detection structure OCDS, the inner crack detection structure ICDS, and the central crack detection structure CCDS. The first path selection circuits PS1 may operate in response to a control signal.

The first path selection circuits PS1 may be connected to the outer conduction segments (e.g., O1 to O4) of the outer crack detection structure OCDS, the inner conduction segments (e.g., I1 to I4) of the inner crack detection structure ICDS, and the central conduction segments (e.g., C1 to C8) of the central crack detection structure CCDS.

In detail, an input terminal of each of the first path selection circuits PS1 may be connected to one of the outer conduction segments (e.g., O1 to O4), one of the inner conduction segments (e.g., I1 to I4), and one of the central conduction segments (e.g., C1 to C8), and an output terminal of each of the first path selection circuits PS1 may be connected to another one of the outer conduction segments (e.g., O1 to O4), another one of the inner conduction segments (e.g., I1 to I4), and another one of the central conduction segments (e.g., C1 to C8). Each of the first path selection circuits PS1 may be between the outer conduction segments (e.g., O1 to O4) and between the inner conduction segments (e.g., I1 to I4).

One end of each of the outer conduction segments (e.g., O1 to O4) and one end of each of the inner conduction segments (e.g., I1 to I4) may be connected to one of the first path selection circuits PS1, and the other end of each of the outer conduction segments (e.g., O1 to O4) and the other end of each of the inner conduction segments (e.g., I1 to I4) may be connected to another one of the first path selection circuits PS1.

Each of the first path selection circuits PS1 may transmit a signal of one of the outer crack detection structure OCDS, the inner crack detection structure ICDS, and the central crack detection structure CCDS to another one of the outer crack detection structure OCDS, the inner crack detection structure ICDS, and the central crack detection structure CCDS. In other words, each of the first path selection circuits PS1 may select which structure among the outer crack detection structure OCDS, the inner crack detection structure ICDS, and the central crack detection structure CCDS to receive a signal from and which structure thereamong to transmit the signal to.

Each of the first path selection circuits PS1 may select and output one of the signals respectively received from the outer crack detection structure OCDS, the inner crack detection structure ICDS, and the central crack detection structure CCDS.

Accordingly, the semiconductor device 1000 may detect cracks in an independent signal multi-branch manner, according to various example embodiments. Because branching conduction segments (e.g., outer, inner, and central conduction segments) are connected to the input terminal of each of the first path selection circuits PS1, each of the first path selection circuits PS1 may receive an independent signal of each conduction segment. Because branching conduction segments (e.g., outer, inner, and central conduction segments) are connected to the output terminal of each of the first path selection circuits PS1, each of the first path selection circuits PS1 may transmit an independent signal of each conduction segment.

For example, the first outer conduction segment O1, the first inner conduction segment I1, and the second central conduction segment C2 may be connected to an input terminal of a first selection circuit PS1a, and the second outer conduction segment O2, the second inner conduction segment I2, and the third central conduction segment C3 may be connected to an output terminal of the first selection circuit PS1a. The first selection circuit PS1a may receive a signal from one of the first outer conduction segment O1, the first inner conduction segment I1, and/or the second central conduction segment C2 and transmit the signal to one of the second outer conduction segment O2, the second inner conduction segment I2, and/or the third central conduction segment C3.

Consequently, according to various example embodiments, the semiconductor device 1000 may detect an exact location of a crack and increase the ability to sense crack penetration in various paths.

Referring back to FIG. 1, in some example embodiments, the first path selection circuits PS1 may include the first selection circuit PS1a, a second selection circuit PS1b, a third selection circuit PS1c, and a fourth selection circuit PS1d. In some example embodiments, the first selection circuit PS1a may be adjacent to a first edge E1 of the outer region EA, the second selection circuit PS1b may be adjacent to a second edge E2 of the outer region EA, the third selection circuit PS1c may be adjacent to a third edge E3 of the outer region EA, and the fourth selection circuit PS1d may be adjacent to a fourth edge E4 of the outer region EA.

In some example embodiments, the first selection circuit PS1a may face the third selection circuit PS1c in the first direction (the X direction), and the second selection circuit PS1b may face the fourth selection circuit PS1d in the second direction (the Y direction).

In some example embodiments, the fourth selection circuit PS1d may be connected to the input end node ENI and the output end node ENO. The input end node ENI may be connected to a test input pad PTI to which a test input signal TSI is applied, and the output end node ENO outputting a test output signal TSO may be connected to a test output pad PTO.

According to some example embodiments, the semiconductor device 1000 may include the second path selection circuit PS2. The second path selection circuit PS2 may be at the center of the central region CA. The second path selection circuit PS2 may be connected to the central crack detection structure CCDS and may control electrical connection of the central crack detection structure CCDS. In detail, the second path selection circuit PS2 may be connected between the central conduction segments (e.g., C1 to C8) of the central crack detection structure CCDS. One end of each of the central conduction segments (e.g., C1 to C8) may be connected to one of the first path selection circuits PS1, and the other end of each of the central conduction segments (e.g., C1 to C8) may be connected to the second path selection circuit PS2. The second path selection circuit PS2 may operate in response to a control signal.

The second path selection circuit PS2 may transmit a signal of one of the central conduction segments (e.g., C1 to C8) to another one of the central conduction segments (e.g., C1 to C8). The second path selection circuit PS2 may allow a test signal to be transmitted in various directions so that the semiconductor device 1000 according to various example embodiments may detect an exact location of a crack and increase the ability to sense crack penetration in various paths.

In some example embodiments, each of the first path selection circuits PS1 and the second path selection circuit PS2 may include a multi-switch device. For example, each of the first path selection circuits PS1 and the second path selection circuit PS2 may include at least one selected from the group consisting of a switch, a multiplexer (MUX), a demultiplexer (DEMUX), and a tri-state buffer.

Various example embodiments of the inventive concepts may include the first path selection circuits PS1 connecting signals among the outer crack detection structure OCDS, the inner crack detection structure ICDS, and/or the central crack detection structure CCDS. The number and positions of first path selection circuits PS1 and the number and positions of conduction segments of each crack detection structure (e.g., OCDS, ICDS, or CCDS) are not limited to those illustrated in the accompanying drawings.

For example, although FIG. 1 illustrates that the number of first path selection circuits PS1 included in the semiconductor device 1000 is four (e.g., PS1a, PS1b, PS1c, and PS1d), various example embodiments of the inventive concepts are not limited thereto. For example, the number of first path selection circuits PS1 may be three or less or five or more and may be adjusted according to the necessity. Each of the first path selection circuits PS1 may be arranged in various positions according to the design of conduction segments for crack detection. Although FIG. 1 illustrates that the number of second path selection circuits PS2 included in the semiconductor device 1000 is one, various example embodiments of the inventive concepts are not limited thereto. For example, there may be a plurality of second path selection circuits PS2.

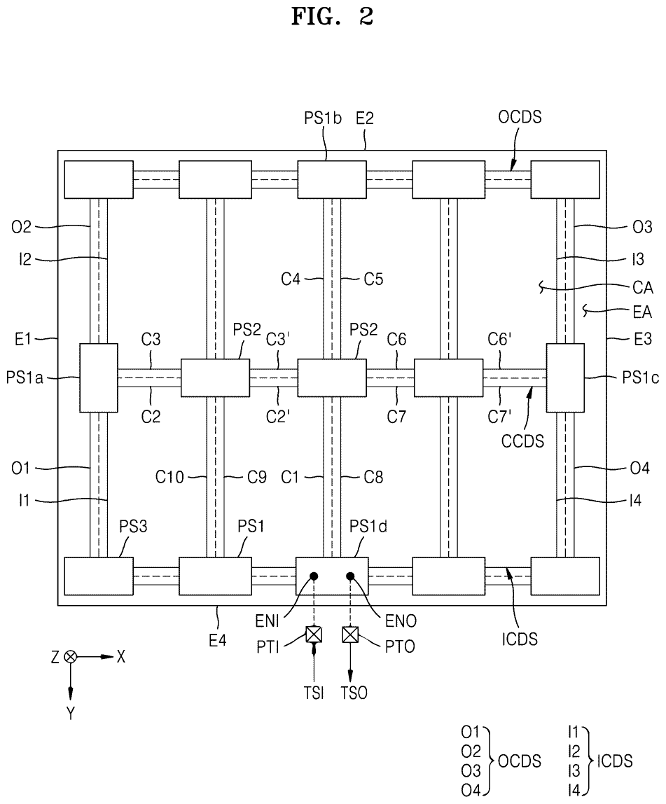

Referring to FIG. 2, according to some example embodiments, the semiconductor device 1000 may include a third path selection circuit PS3. The third path selection circuit PS3 may be connected between the first path selection circuits PS1. The third path selection circuit PS3 may be inserted in the path of the outer conduction segments (e.g., O1 to O4) described in FIG. 1. The third path selection circuit PS3 may be further connected in the path of the first outer conduction segment O1, the second outer conduction segment O2, the third outer conduction segment O3, and the fourth outer conduction segment O4. The third path selection circuit PS3 may be inserted in the path of the inner conduction segments I1 to I4 described in FIG. 1. The third path selection circuit PS3 may be further connected in the path of at least one of the first inner conduction segment I1, the second inner conduction segment I2, the third inner conduction segment I3, and the fourth inner conduction segment I4.

In some example embodiments, there may be a plurality of second path selection circuits PS2. For example, at least some of the second path selection circuits PS2 may be inserted in the path of and the central conduction segments (e.g., C1 to C8) described in FIG. 1.

For example, as shown in FIG. 2, at least one of the second path selection circuits PS2 may be further connected to the path of the second and third central conduction segments C2, C3. For example, as shown in FIG. 2, at least one of the second path selection circuits PS2 may be further connected to the path of the sixth and seventh conduction segments C6, C7. In some example embodiments, the central crack detection structure CCDS may further comprise ninth and tenth central conduction segments C9, C10. The ninth and tenth central conduction segments C9, C10 may cross the sub regions (e.g., S1, S2, S3, and S4)

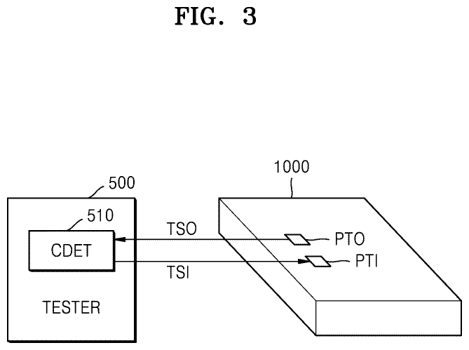

FIG. 3 is a block diagram of a test system according to some example embodiments.

Referring to FIGS. 1 and 3, the test system may include a tester 500 and the semiconductor device 1000. The semiconductor device 1000 may include crack detection structures (e.g., the outer crack detection structure OCDS, the inner crack detection structure ICDS, and the central crack detection structure CCDS), as described above. The crack detection structures may form a conduction loop together with the first path selection circuits PS1 and/or the second path selection circuit PS2 and may connect the input end node ENI to the output end node ENO in an annular shape.

Various example embodiments of the inventive concepts may include the first path selection circuits PS1 and the second path selection circuit PS2, as described above, and accordingly, the conduction loop may be formed via different crack detection structures rather than only one of the crack detection structures.

The input end node ENI and the output end node ENO may be respectively connected to the test input pad PTI and the test output pad PTO, which are formed in the semiconductor device 1000, e.g., in the surface of the semiconductor die. The conduction loop may be connected through the test input and output pads PTI and PTO to the tester 500 outside the semiconductor device 1000.

The tester 500 may include a crack detector CDET or a crack detector 510. The crack detector 510 may apply the test input signal TSI to the semiconductor device 1000 through the test input pad PTI and receive the test output signal TSO, which corresponds to a signal obtained after the test input signal TSI passes through the conduction loop of a crack detection structure, through the test output pad PTO. The crack detector 510 may compare the test input signal TSI with the test output signal TSO and determine whether a crack occurs in the semiconductor die.

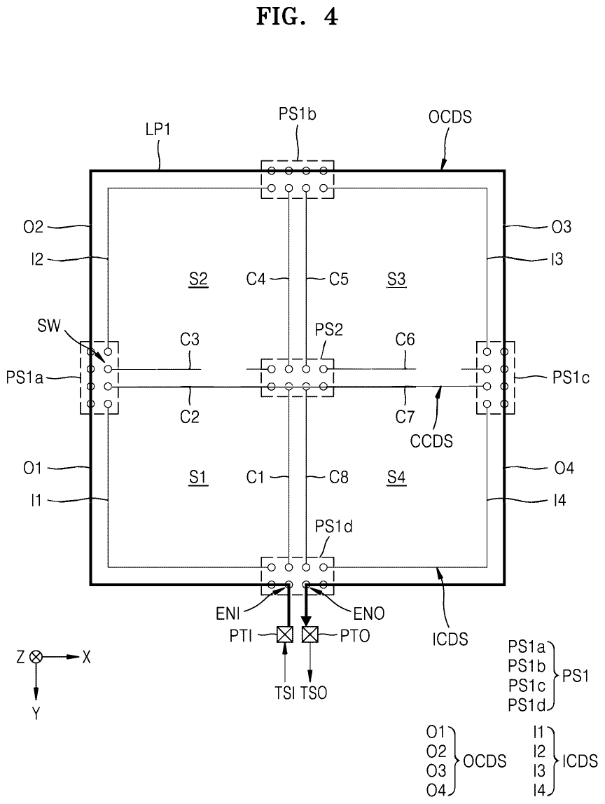

FIGS. 4 to 6 are plan views illustrating the layout of a semiconductor device according to some example embodiments and show the flows of test signals for crack detection of the semiconductor device. FIGS. 4 to 6 illustrate that each of the first path selection circuits PS1 and the second path selection circuit PS2 includes a switch SW.

According to various example embodiments, a semiconductor device may include the outer crack detection structure OCDS, the inner crack detection structure ICDS, and/or the central crack detection structure CCDS and the first path selection circuits PS1 and/or the second path selection circuit PS2 to determine the occurrence of a crack and the location of the crack therein.

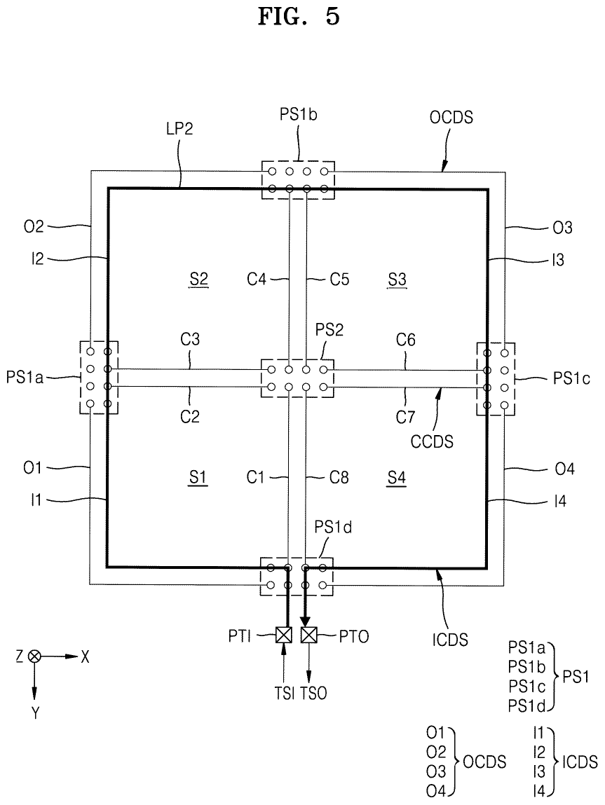

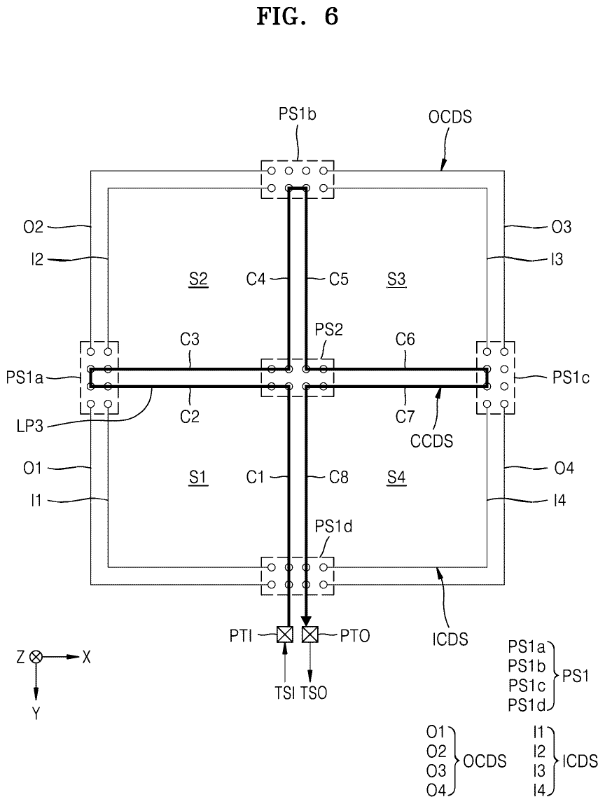

According to some example embodiments, as illustrated in FIG. 4, whether a crack occurs in an outer portion of the semiconductor device may be determined through a conduction loop LP1, which is constituted of the outer crack detection structure OCDS and the first path selection circuits PS1. Subsequently, as illustrated in FIG. 5, whether a crack occurs in an inner portion of the semiconductor device may be determined through a conduction loop LP2, which is constituted of the inner crack detection structure ICDS and the first path selection circuits PS1. Subsequently, as illustrated in FIG. 6, whether a crack occurs in a central portion of the semiconductor device may be determined through a conduction loop LP3, which is constituted of the central crack detection structure CCDS, the first path selection circuits PS1, and the second path selection circuit PS2. The order of determining whether a crack occurs in FIGS. 4 to 6 may be variously changed.

Consequently, whether a crack occurs in each of the outer, inner, and central portions of a semiconductor die (or the semiconductor device 1000) may be determined. Here, when it is determined that a crack has occurred, an additional test may be performed to determine an exact location of the crack.

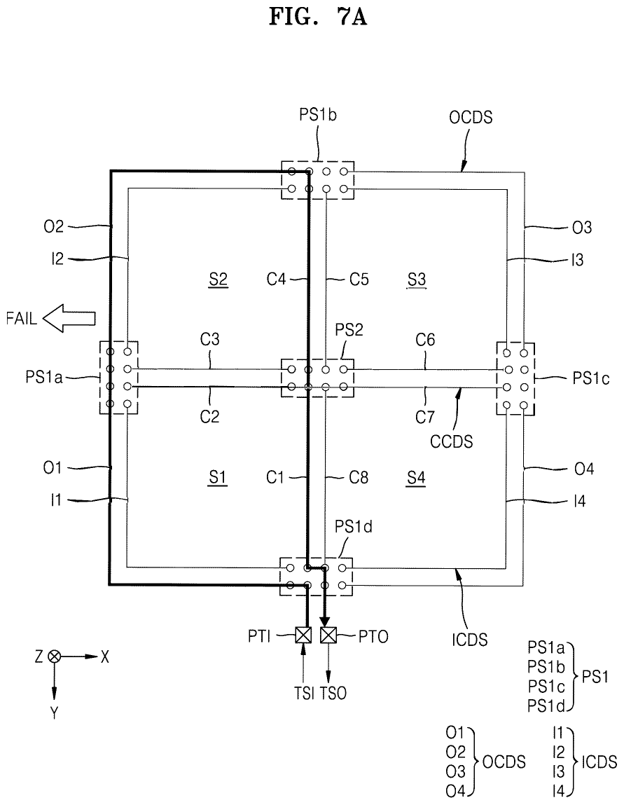

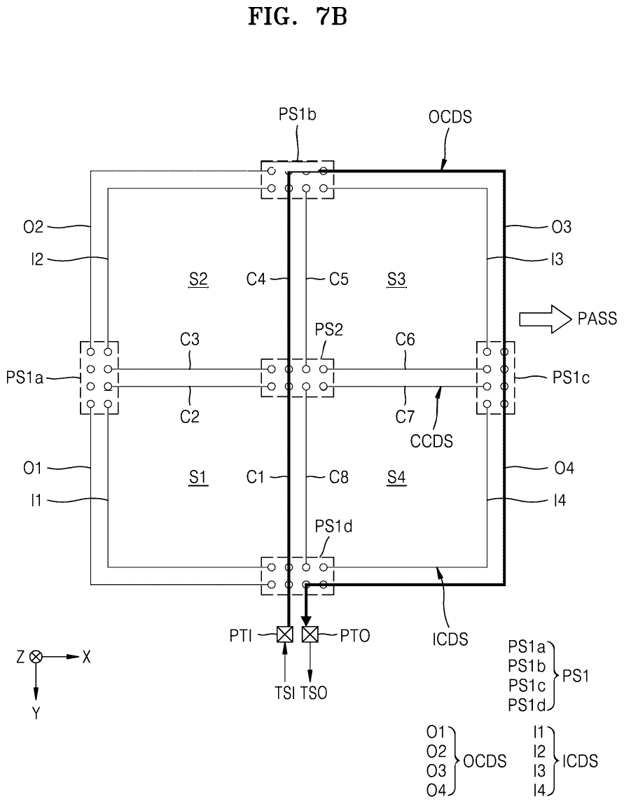

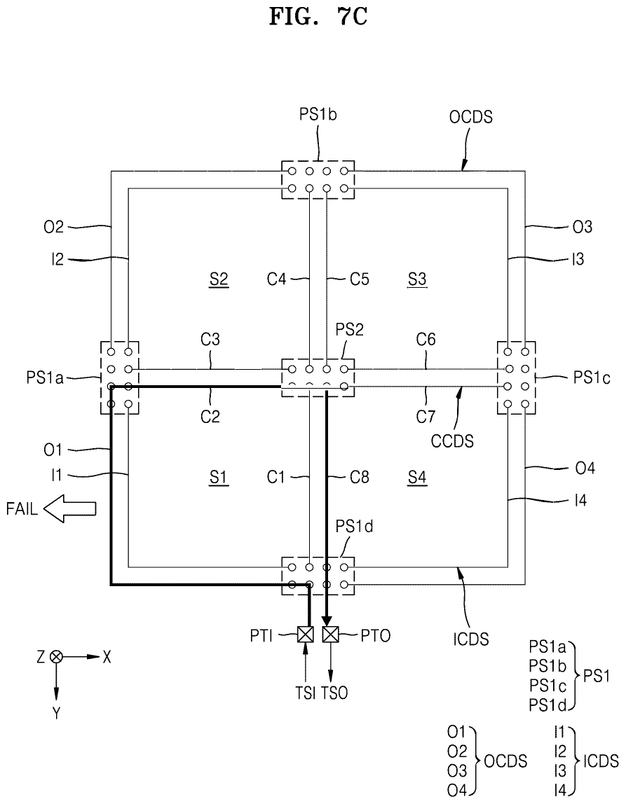

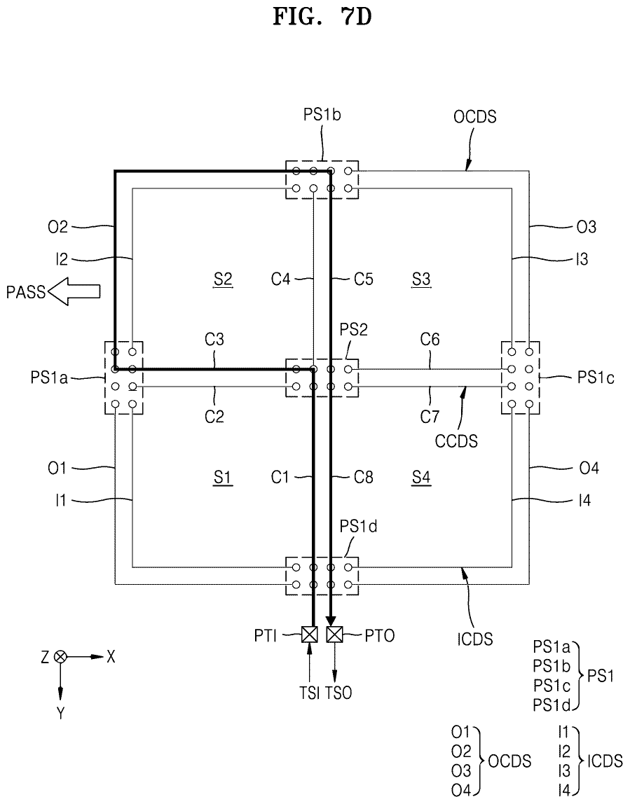

FIGS. 7A to 7D are plan views illustrating the layout of a semiconductor device according to some example embodiments and show the flows of test signals for crack detection of the semiconductor device. FIGS. 7A to 7D illustrate the flows of signals to determine the exact location of a crack when it is determined that the crack has occurred in the conduction loop LP1 (e.g., the outer portion) in FIG. 4 among the conduction loops LP1, LP2, and LP3 respectively illustrated in FIGS. 4 to 6.

As shown in FIGS. 7A and 7B, the first path selection circuits PS1 and the second path selection circuit PS2 may be controlled to form a conduction loop surrounding two sub regions.

As shown in FIG. 7A, to determine whether a crack has occurred in an outer portion adjacent to the first sub region S1 and the second sub region S2, the first path selection circuits PS1 and the second path selection circuit PS2 may be controlled such that the test input signal TSI is transmitted along the first outer conduction segment O1, the second outer conduction segment O2, the fourth central conduction segment C4, and the first central conduction segment C1 and output as the test output signal TSO.

As shown in FIG. 7B, to determine whether a crack has occurred in an outer portion adjacent to the third sub region S3 and the fourth sub region S4, the first path selection circuits PS1 and the second path selection circuit PS2 may be controlled such that the test input signal TSI is transmitted along the first central conduction segment C1, the fourth central conduction segment C4, the third outer conduction segment O3, and the fourth outer conduction segment O4 and output as the test output signal TSO.

When it is determined that a crack has occurred in the case of FIG. 7A (e.g., FAIL is determined) and no cracks has occurred in the case of FIG. 7B (e.g., PASS is determined), the first path selection circuits PS1 and the second path selection circuit PS2 may be controlled to form a conduction loop surrounding one sub region so as to narrow the range, as shown in FIGS. 7C and 7D.

As shown in FIG. 7C, to determine whether a crack has occurred in an outer portion adjacent to the first sub region S1, the first path selection circuits PS1 and the second path selection circuit PS2 may be controlled such that the test input signal TSI is transmitted along the first outer conduction segment O1, the second central conduction segment C2, and the eighth central conduction segment C8 and output as the test output signal TSO.

As shown in FIG. 7D, to determine whether a crack has occurred in an outer portion adjacent to the second sub region S2, the first path selection circuits PS1 and the second path selection circuit PS2 may be controlled such that the test input signal TSI is transmitted along the first central conduction segment C1, the third central conduction segment C3, the second outer conduction segment O2, the fifth central conduction segment C5, and the eighth central conduction segment C8 and output as the test output signal TSO.

Based on the result of determining whether a crack has occurred in the example of FIG. 7C and the example of FIG. 7D, it may be determined which of a plurality of sub regions (e.g., S1 to S4) the crack has occurred in an outer portion adjacent to. When it is determined that a crack has occurred in the case of FIG. 7C (e.g., FAIL is determined) and no cracks has occurred in the case of FIG. 7C (e.g., PASS is determined), it may be determined that the crack has occurred in the outer portion adjacent to the first sub region S1.

When it is determined that a crack has occurred in the conduction loop LP2 (e.g., an inner portion) in FIG. 5 by using the crack detection determination method described with reference to FIGS. 7A to 7D, it may be determined which of a plurality of sub regions (e.g., S1 to S4) the crack has occurred in an inner portion adjacent to.

FIGS. 7A to 7D show just one example of a conduction loop selected through the first path selection circuits PS1 and the second path selection circuit PS2, and the example embodiments are not limited thereto. For example, in a conduction loop in FIG. 7C, the first central conduction segment C1 may be selected instead of the eighth central conduction segment C8.

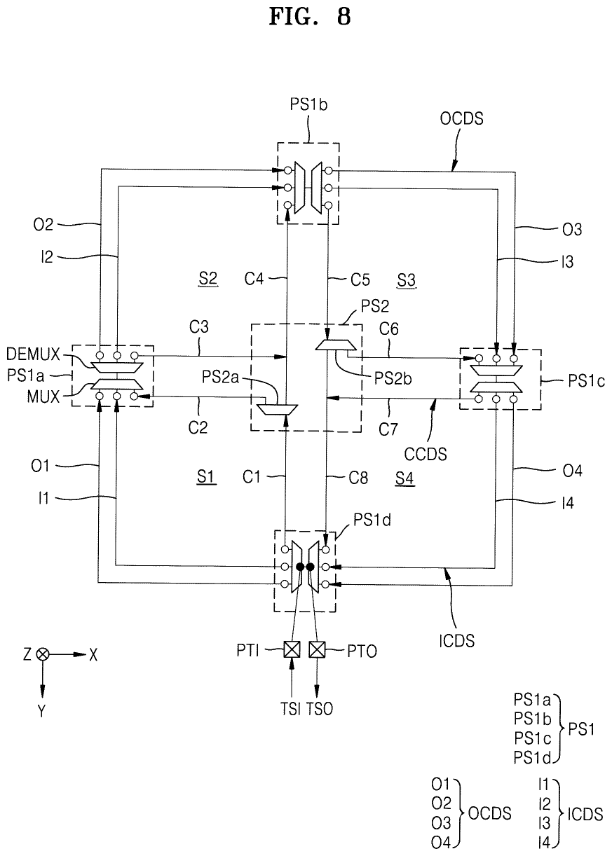

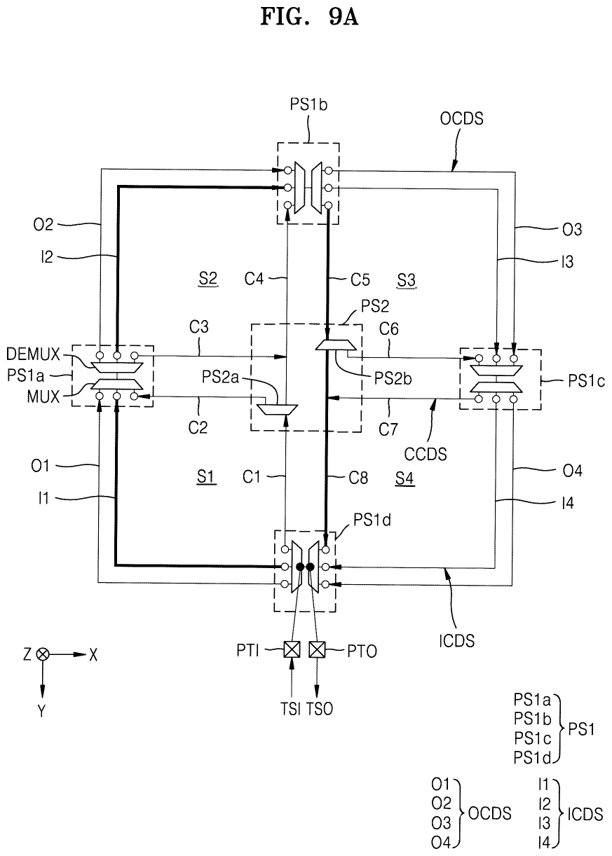

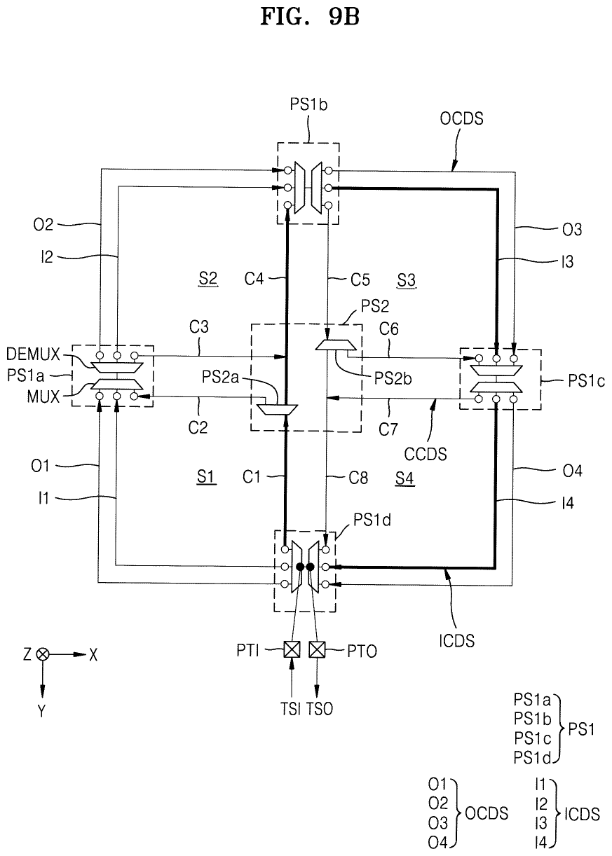

FIG. 8 is a plan view illustrating the layout of a semiconductor device according to some example embodiments. FIGS. 9A and 9B are plan views illustrating the layout of a semiconductor device according to some example embodiments and show the flows of test signals for crack detection of the semiconductor device.

Referring to FIG. 8, according to various example embodiments, the second path selection circuit PS2 may include a first sub selection circuit PS2a and a second sub selection circuit PS2b. In some example embodiments, each of the first path selection circuits PS1 may include a MUX and a DEMUX, each of the first sub selection circuit PS2a and the second sub selection circuit PS2b of the second path selection circuit PS2 may include a DEMUX. Accordingly, a signal flowing in a conduction segment may be unidirectional.

Referring to FIG. 9A, the second sub selection circuit PS2b may include a DEMUX such that a signal is transmitted sequentially through the first inner conduction segment I1, the second inner conduction segment I2, the fifth central conduction segment C5, and the eighth central conduction segment C8.

Referring to FIG. 9B, the first sub selection circuit PS2a may include a DEMUX such that a signal is transmitted sequentially through the first central conduction segment C1, the fourth central conduction segment C4, the third inner conduction segment I3, and the fourth inner conduction segment I4.

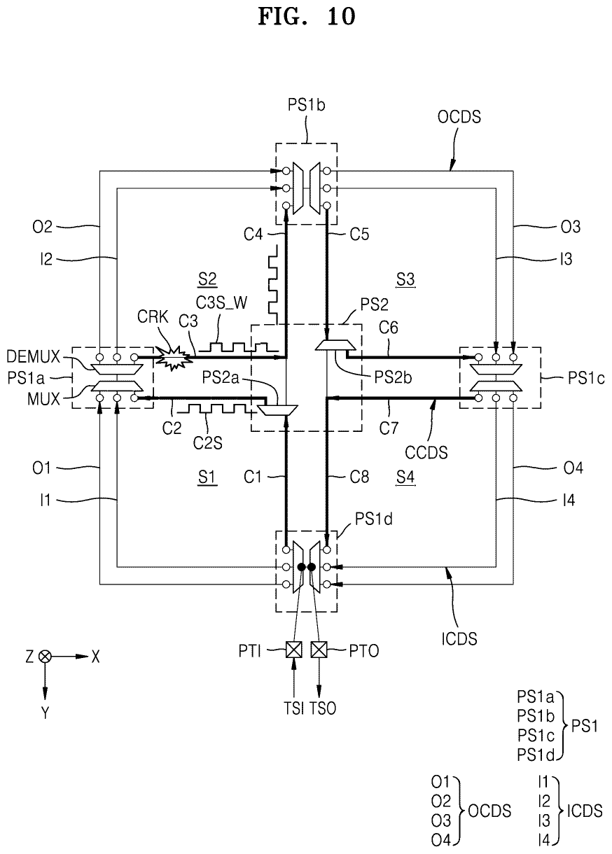

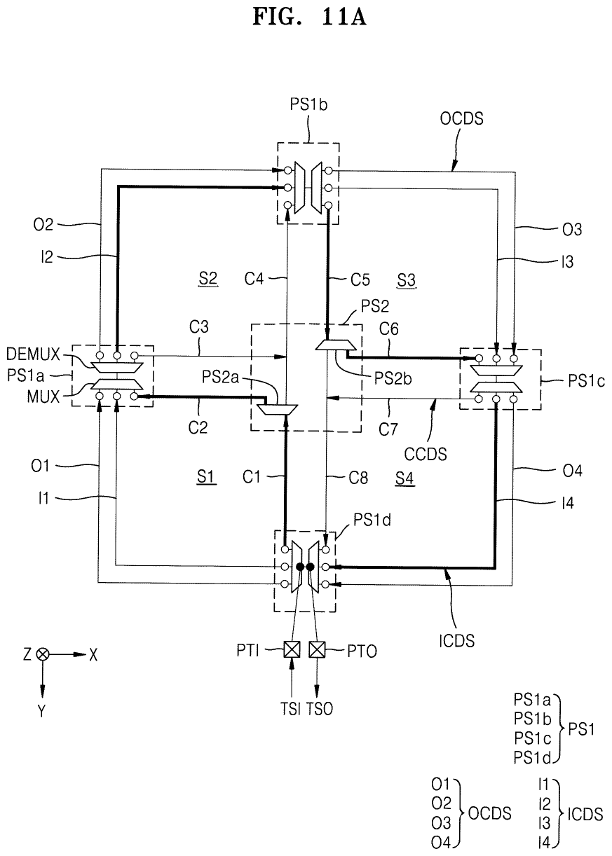

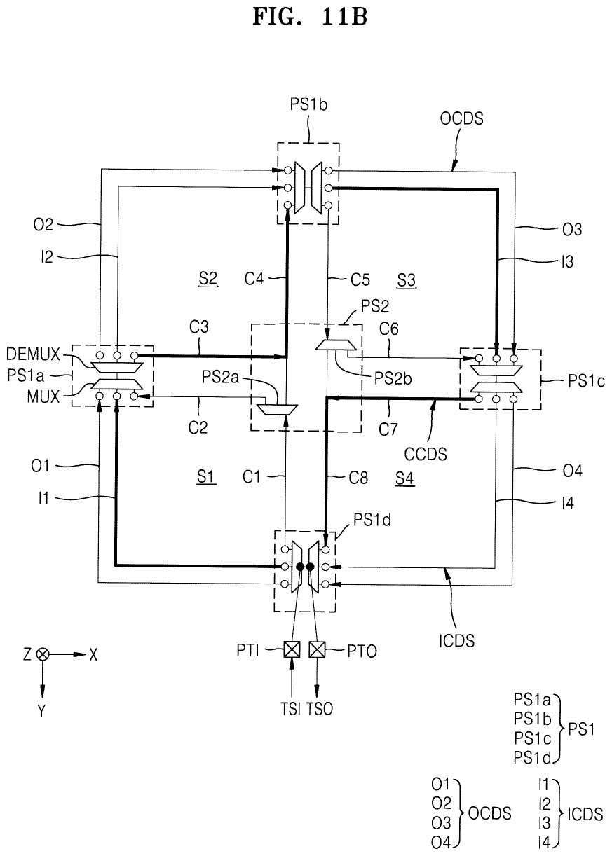

FIG. 10 is a plan view illustrating the layout of a semiconductor device according to some example embodiments and shows the flow of a test signal for crack detection of the semiconductor device. FIGS. 11A and 11B are plan views illustrating the layout of a semiconductor device according to some example embodiments and show the flows of test signals for crack detection of the semiconductor device.

As described above, in some example embodiments, two central conduction segments among a plurality of central conduction segments of the central crack detection structure CCDS may be adjacent to each other. For example, the first and eighth central conduction segments C1 and C8 may be adjacent to each other, the second and third central conduction segments C2 and C3 may be adjacent to each other, the fourth and fifth central conduction segments C4 and C5 may be adjacent to each other, and the sixth and seventh central conduction segments C6 and C7 may be adjacent to each other.

Therefore, even when a crack CRK occurs in the third central conduction segment C3 as shown in FIG. 10, a signal may be transmitted to the fourth central conduction segment C4 because of coupling between the second central conduction segment C2 and the third central conduction segment C3. In other words, an error signal C3S_W may occur in the third central conduction segment C3 due to a signal C2S of the second central conduction segment C2. In addition, even when a conduction loop that does not go through the third central conduction segment C3 is set, the error signal C3S_W may be transmitted to the fourth central conduction segment C4 due to the coupling described above.

To prevent or reduce in likelihood this error, when it is determined whether a crack occurs in a central portion as shown in FIG. 6, the determination process may be divided into two tests as shown in FIGS. 11A and 11B. In other words, as shown in FIGS. 11A and 11B, two adjacent central conduction segments may not be included in one conduction loop.

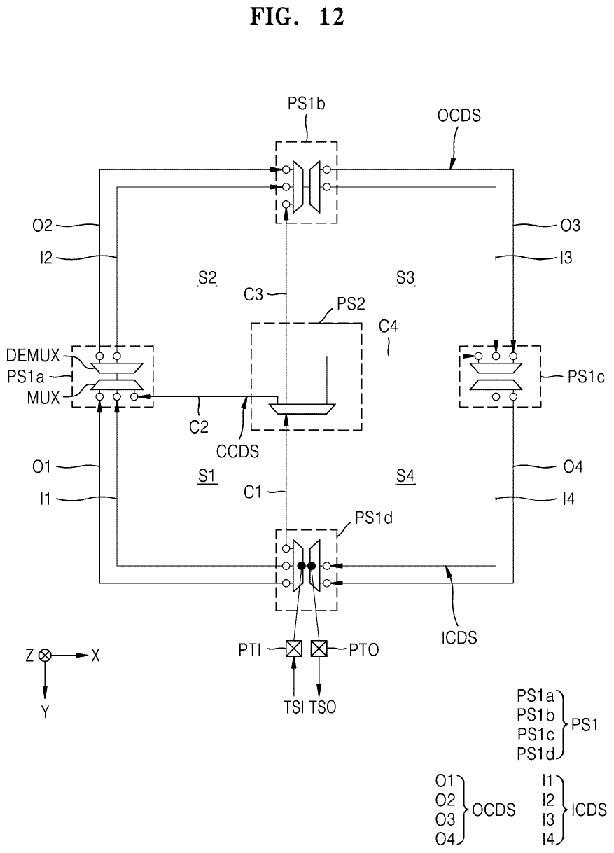

FIG. 12 is a plan view illustrating the layout of a semiconductor device according to some example embodiments. Referring to FIG. 12, unlike the example in FIG. 8, the second path selection circuit PS2 may secure space in the central region CA by including one DEMUX.

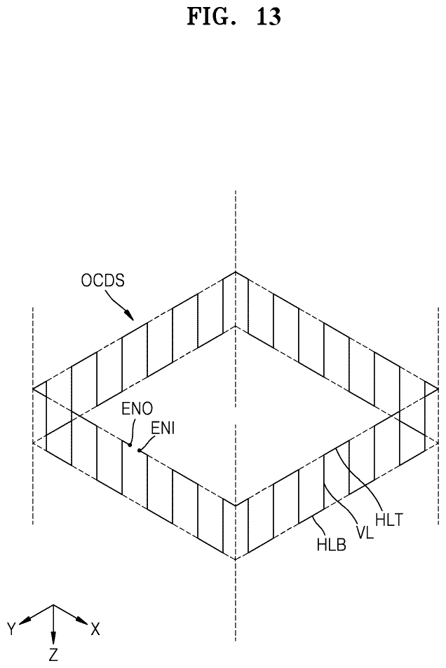

FIG. 13 is a perspective view illustrating the outer crack detection structure OCDS according to some example embodiments.

Referring to FIG. 13, in some example embodiments, the outer crack detection structure OCDS may have a three-dimensional (3D) structure. The outer crack detection structure OCDS may include a single conduction loop. A semiconductor die may include a first conductive layer and a second conductive layer below the first conductive layer. These conductive layers may include a metal layer, in which metal lines are patterned, and/or a poly layer, in which polysilicon lines are patterned. The outer crack detection structure OCDS may extend in a vertical direction (a Z direction) across the first conductive layer and the second conductive layer.

The outer crack detection structure OCDS may include a plurality of top horizontal lines HLT formed in the first conductive layer, a plurality of bottom horizontal lines HLB formed in the second conductive layer, and a plurality of vertical lines VL connecting the top horizontal lines HLT to the bottom horizontal lines HLB. The top horizontal lines HLT, the bottom horizontal lines HLB, and the vertical lines VL may be alternately arranged in the outer crack detection structure OCDS to surround the central region CA of the semiconductor die, thereby connecting the input end node ENI to the output end node ENO.

In some example embodiments, the input end node ENI and the output end node ENO may be respectively connected to input and output pads formed in the surface of the semiconductor die, and the outer crack detection structure OCDS may be connected to an external tester through the input and output pads. In other example embodiments, the input end node ENI and the output end node ENO may be connected to a test circuit, such as a crack detector, which is formed in a portion of the central region of the semiconductor die.

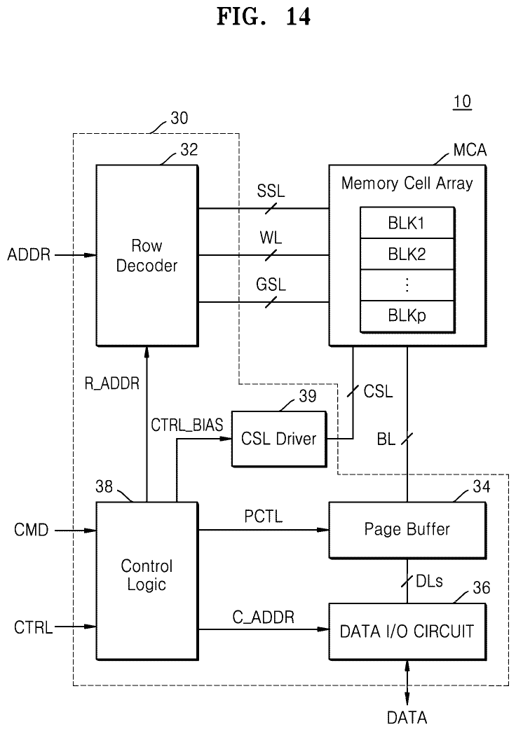

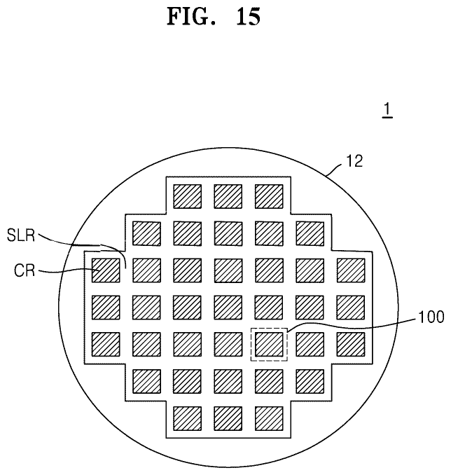

FIG. 14 is a block diagram of a semiconductor device according to some example embodiments. FIG. 15 is a schematic plan view of a semiconductor device according to some example embodiments.

Referring to FIG. 14, a semiconductor device 10 may include a memory cell array MCA and a peripheral circuit 30. The memory cell array MCA may include a plurality of memory cell blocks BLK1 to BLKp. Each of the memory cell blocks BLK1 to BLKp may include a plurality of memory cells. The memory cell blocks BLK1 to BLKp may be connected to the peripheral circuit 30 through a bit line BL, a word line WL, a string select line SSL, and a ground select line GSL.

The peripheral circuit 30 may include a row decoder 32, a page buffer 34, a data input/output (I/O) circuit 36, a control logic 38, and a common source line (CSL) driver 39. The peripheral circuit 30 may further include various circuits, such as an I/O interface, a voltage generation circuit generating various voltages necessary for the operation of the semiconductor device 10, and an error correction circuit correcting error in data read from the memory cell array MCA.

The memory cell array MCA may be connected to the row decoder 32 through the word line WL, the string select line SSL, and the ground select line GSL and to the page buffer 34 through the bit line BL. The memory cells included in the memory cell blocks BLK1 to BLKp of the memory cell array MCA may respectively include flash memory cells. The memory cell array MC may include a 3D memory cell array. The 3D memory cell array may include a plurality of NAND strings, and each NAND string may include a plurality of memory cells respectively connected to a plurality of word lines WL vertically stacked on each other.

The peripheral circuit 30 may receive an address ADDR, a command CMD, and a control signal CTRL from the outside of the semiconductor device 10 and may exchange data with a device outside the semiconductor device 10.

In response to the address ADDR, the row decoder 32 may select at least one of the memory cell blocks BLK1 to BLKp and select the word line WL, the string select line SSL, and the ground select line GSL of the selected memory cell block. The row decoder 32 may transmit, to the word line WL of the selected memory cell block, a voltage for performing a memory operation.

The page buffer 34 may be connected to the memory cell array MCA through the bit line BL. In a program operation, the page buffer 34 may operate as a write driver and apply, to the bit line BL, a voltage corresponding to data to be stored in the memory cell array MCA. In a read operation, the page buffer 34 may operate as a sense amplifier and sense data stored in the memory cell array MCA. The page buffer 34 may operate according to a control signal PCTL provided from the control logic 38.

The data I/O circuit 36 may be connected to the page buffer 34 through data lines DLs. In a program operation, the data I/O circuit 36 may receive program data from a memory controller (not shown) and provide the program data to the page buffer 34 based on a column address C_ADDR provided from the control logic 38. In a read operation, the data I/O circuit 36 may provide read data stored in the page buffer 34 to the memory controller based on the column address C_ADDR provided from the control logic 38.

The data I/O circuit 36 may transmit an address or an instruction to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and the column address C_ADDR to the data I/O circuit 36. The control logic 38 may generate various kinds of internal control signals, which are used in the semiconductor device 10, in response to the control signal CTRL. For example, the control logic 38 may adjust a voltage level applied to the word line WL and the bit line BL in a memory operation, such as a program operation or an erase operation.

The CSL driver 39 may be connected to the memory cell array MCA through a common source line CSL. The CSL driver 39 may apply a common source voltage (e.g., a power supply voltage) or a ground voltage to the common source line CSL, based on a control signal CTRL_BIAS of the control logic 38.

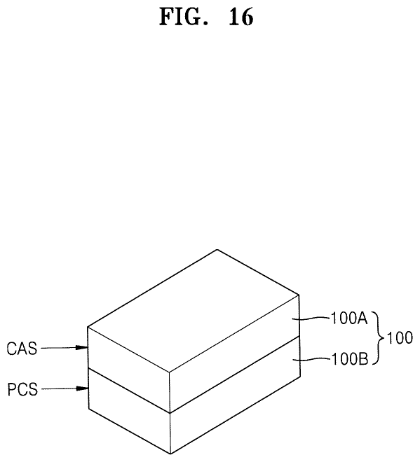

FIG. 15 is a schematic plan view of a semiconductor device 1 according to some example embodiments. FIG. 16 is a perspective view illustrating an example of a semiconductor die 100 according to some example embodiments.

Referring to FIG. 15, the semiconductor device 1 may include a substrate (or a wafer) 12, which includes a plurality of chip regions CR and a scribe lane region SLR surrounding each of the chip regions CR. The chip regions CR may be arranged in a matrix on the substrate 12. The scribe lane region SLR may include a cutting region for singulation of the chip regions CR.

Each of the chip regions CR may be a high-density region having a relatively high pattern density, and the scribe lane region SLR may be a low-density region having a relatively low pattern density. The chip regions CR may include a cell array region of a semiconductor memory device, a peripheral circuit region, and a core region, wherein the peripheral circuit region and the core region include circuits configured to be electrically connected to cell arrays included in the cell array region. In some example embodiments, each of the chip regions CR may include at least one non-volatile memory device. In some example embodiments, the non-volatile memory device may include NAND flash memory, vertical NAND (VNAND) flash memory, NOR flash memory, resistive random-access memory (RRAM), phase-change RAM (PRAM), magnetoresistive RAM (MRAM), ferroelectric RAM (FRAM), spin transfer torque (STT) RAM, or a combination thereof. The non-volatile memory device may have a 3D array structure. For example, each of the chip regions CR may include the memory cell array MCA and the peripheral circuit 30, which are included in the semiconductor device 10 described with reference to FIG. 14. In some example embodiments, the non-volatile memory device may further include a volatile memory device, such as dynamic RAM (DRAM).

Referring to FIGS. 15 and 16, the semiconductor die 100 may include a first semiconductor die 100A including a cell array structure CAS and a second semiconductor die 100B including a peripheral circuit structure PCS, wherein the first semiconductor die 100A is vertically stacked on the second semiconductor die 100B. As described below with reference to FIG. 18, the inner crack detection structure ICDS may be arranged in a portion of the first semiconductor die 100A and a portion of the second semiconductor die 100B.

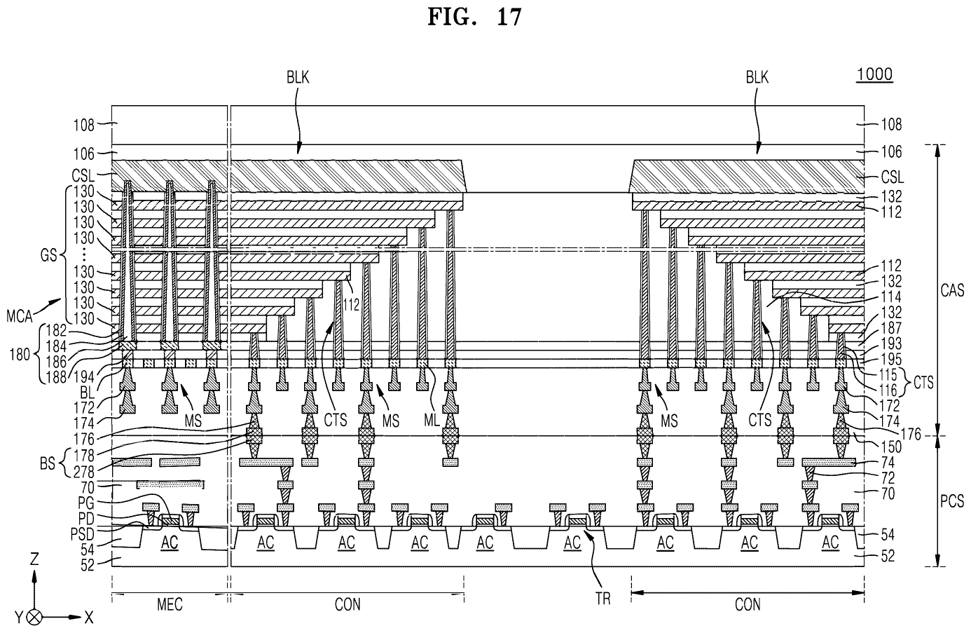

FIG. 17 is a cross-sectional view of partial regions of a peripheral circuit structure and a cell array structure of a semiconductor device, according to some example embodiments.

Referring to FIG. 17, a semiconductor device 1000 may include the cell array structure CAS and the peripheral circuit structure PCS overlapping the cell array structure CAS in the vertical direction (the Z direction). The cell array structure CAS may include a memory cell region MEC, in which the memory cell array MCA is arranged, and a connection region CON at a side of the memory cell region MEC in the first direction (the X direction).

In some example embodiments, the semiconductor device 1000 may have a chip-to-chip (C2C) structure. The C2C structure may be obtained by forming the cell array structure CAS on a first wafer, forming the peripheral circuit structure PCS on a second wafer that is different from the first wafer, and then connecting the cell array structure CAS to the peripheral circuit structure PCS in a bonding manner. For example, the bonding manner may include a method of electrically connecting a first bonding metal pad 178 formed on an uppermost metal layer of the cell array structure CAS to a second bonding metal pad 278 formed on an uppermost metal layer of the peripheral circuit structure PCS. In some example embodiments, when the first bonding metal pad 178 and the second bonding metal pad 278 include copper (Cu), the bonding manner may be Cu—Cu bonding. In some example embodiments, each of the first bonding metal pad 178 and the second bonding metal pad 278 may include aluminum (Al) or tungsten (W).

The peripheral circuit structure PCS may include a substrate 52, a plurality of circuits on the substrate 52, and a multi-layer wiring structure which connects the circuits to each other or to elements in the memory cell region MEC of the cell array structure CAS.

The substrate 52 may include a semiconductor substrate. For example, the substrate 52 may include Si, Ge, or SiGe. An active region AC may be defined in the substrate 52 by an isolation film 54. A plurality of transistors TR forming a plurality of circuits may be formed on the active region AC. Each of the transistors TR may include a gate dielectric film PD and a gate PG, which are sequentially stacked on the substrate 52, and a plurality of ion implantation regions PSD in the active region AC. The ion implantation regions PSD are respectively formed at opposite sides of the gate PG. Each of the ion implantation regions PSD may form a source region or a drain region of a transistor TR.

The multi-layer wiring structure of the peripheral circuit structure PCS may include a plurality of contact plugs 72 and a plurality of conductive lines 74. At least some of the conductive lines 74 may be configured to be electrically connected to the transistors TR. The contact plugs 72 may be configured to connect selected ones of the transistors TR to selected ones of the conductive lines 74. The transistors TR and the multi-layer wiring structure of the peripheral circuit structure PCS may be covered with an interlayer insulating film 70. The interlayer insulating film 70 may include a silicon oxide film, a silicon nitride film, an SiON film, an SiOCN film, or a combination thereof.

A plurality of circuits of the peripheral circuit structure PCS may include various circuits of the peripheral circuit 30 described above with reference to FIG. 14. In some example embodiments, the peripheral circuit structure PCS may further include unit elements, such as a resistor and a capacitor. The transistors TR, the contact plugs 72, and the conductive lines 74 of the peripheral circuit structure PCS may form a circuit region. The transistors TR may be configured to be electrically connected to the memory cell region MEC and the connection region CON through a plurality of wiring structures. The wiring structures may include a plurality of contact structures CTS in the connection region CON of the cell array structure CAS.

As shown in FIG. 17, the memory cell region MEC of each of memory cell blocks BLK in a pair may include a plurality of gate lines 130 sequentially stacked in the vertical direction (the Z direction), and the connection region CON of each of the memory cell blocks BLK may include a plurality of conductive pad regions 112 integrally connected to the gate lines 130, respectively.

The gate lines 130 and the conductive pad regions 112 may include metal, metal silicide, impurity-doped semiconductor, or a combination thereof. For example, the gate lines 130 and the conductive pad regions 112 may include metal such as tungsten, nickel, cobalt, or tantalum, metal silicide such as tungsten silicide, nickel silicide, cobalt silicide, or tantalum silicide, doped polysilicon, or a combination thereof.

Each of the memory cell blocks BLK may include a common source line CSL. Two common source lines CSL respectively included in the memory cell blocks BLK may be separated from the peripheral circuit structure PCS in the vertical direction (the Z direction). The common source lines CSL respectively included in the memory cell blocks BLK may be separated from each other in the first direction (the X direction). The common source lines CSL may be covered with an insulating film 106 and a protective film 108.

A plurality of first bonding metal pads 178 may be arranged in the top surface of the cell array structure CAS adjacent to the peripheral circuit structure PCS. Each of the first bonding metal pads 178 may be insulated by an interlayer insulating film 150 in the cell array structure CAS. The interlayer insulating film 150 may include a silicon oxide film, a silicon nitride film, or a combination thereof.

The peripheral circuit structure PCS may include a plurality of second bonding metal pads 278 on the multi-layer wiring structure. The second bonding metal pads 278 may be respectively bonded to the first bonding metal pads 178 of the cell array structure CAS and configured to be electrically connected to the first bonding metal pads 178. The first bonding metal pads 178 and the second bonding metal pads 278 may form a plurality of bonding structures BS. The interlayer insulating film 70 may cover the transistors TR, the contact plugs 72, the conductive lines 74, and the second bonding metal pads 278.

In some example embodiments, the contact plugs 72 and the conductive lines 74 of the peripheral circuit structure PCS may include, but not limited to, tungsten, aluminum, copper, or a combination thereof. The isolation film 54 may include a silicon oxide film, a silicon nitride film, or a combination thereof. The interlayer insulating film 70 may include a silicon oxide film, a silicon nitride film, or a combination thereof. The first bonding metal pads 178 and the second bonding metal pads 278 of the bonding structures BS may include copper, aluminum, or tungsten.

The cell array structure CAS may include a memory cell array MCA between the peripheral circuit structure PCS and a common source line CSL. In the memory cell region MEC and the connection region CON, a gate stack GS may be between the peripheral circuit structure PCS and the common source line CSL. The gate stack GS may include the gate lines 130 and the conductive pad regions 112 respectively and integrally connected with the gate lines 130. A portion of the gate stack GS in the memory cell region MEC may form the memory cell array MCA. The gate lines 130 of the gate stack GS may be arranged in the memory cell region MEC, may extend in a horizontal direction parallel with the common source line CSL, and may overlap each other in the vertical direction (the Z direction). The gate lines 130 may include a plurality of word lines WL, a ground select line GSL, and a string select line SSL.

The conductive pad regions 112 of the gate stack GS of the cell array structure CAS may form a stepped connection part in the connection region CON. Each of the conductive pad regions 112 may be integrally connected to a selected one of the gate lines 130.

In the memory cell array MCA, two string select lines SSL adjacent to each other in the second direction (the Y direction) may be separated from each other by a string select line cut region. The string select line cut region may be filled with an insulating film. The insulating film may include an oxide film, a nitride film, or a combination thereof. In some example embodiments, at least a portion of the string select line cut region may be filled with an air gap. The term “air” used herein may refer to the atmosphere or other gases that may exist in manufacturing processes.

The gate lines 130 and the conductive pad regions 112 may include metal, conductive metal nitride, or a combination thereof. For example, the gate lines 130 and the conductive pad regions 112 may include, but not limited to, tungsten, nickel, cobalt, tantalum, tungsten nitride, titanium nitride, tantalum nitride, or a combination thereof.

As shown in FIG. 17, the cell array structure CAS may include a plurality of insulating films 132 covering the top and bottom surfaces of each of the gate lines 130. The insulating films 132 may include silicon oxide, silicon nitride, or SiON.

In the memory cell region MEC, a plurality of channel structures 180 may extend lengthwise in the vertical direction (the Z direction) through the gate lines 130 and the insulating films 132 and may be connected to the common source line CSL. The channel structures 180 may be spaced apart from each other in the first direction (the X direction) and the second direction (the Y direction).

Each of the channel structures 180 may include a gate dielectric film 182, a channel region 184, a buried insulating film 186, and a drain region 188. The channel region may include doped polysilicon and/or undoped polysilicon. The channel region 184 may have a cylindrical shape. The internal space of the channel region 184 may be filled with the buried insulating film 186. The channel region 184 may include a portion in contact with the common source line CSL. The buried insulating film 186 may include an insulating material. For example, the buried insulating film 186 may include silicon oxide, silicon nitride, SiON, or a combination thereof. In some example embodiments, the buried insulating film 186 may be omitted. In this case, the channel region 184 may have a pillar structure with no internal space. The drain region 188 may include impurity-doped polysilicon, metal, conductive metal nitride, or a combination thereof. Examples of the metal of the drain region 188 may include tungsten, nickel, cobalt, and tantalum. A plurality of drain regions 188 may be insulated from each other by an intermediate insulating film 187. The intermediate insulating film 187 may include an oxide film, a nitride film, or a combination thereof.

Although it is illustrated in FIG. 17 that each of the channel structures 180 includes the gate dielectric film 182 and the gate dielectric film 182 extends lengthwise in the vertical direction (the Z direction) along the channel region 184, the inventive concepts are not limited thereto, and various changes and modifications may be made in the example embodiments.

In the connection region CON of the cell array structure CAS, the widths in the horizontal direction (e.g., the X direction) of the conductive pad regions 112 forming a stepped connection part may decrease away from the common source line CSL. In some example embodiments, a plurality of dummy channel structures (not shown) passing through the conductive pad regions 112 may be arranged in the connection region CON. The dummy channel structures may support the gate stack GS and the conductive pad regions 112, thereby preventing or reducing in likelihood undesirable structural deformation, such as bending or breaking, of the gate stack GS or the conductive pad regions 112.

A plurality of bit lines BL may be arranged on the channel structures 180 in the cell array structure CAS. A plurality of bit line contact pads 194 may be between the channel structures 180 and the bit lines BL. The drain region 188 of each of the channel structures 180 may be connected to one bit line BL among the bit lines BL through a bit line contact pad 194. The bit line contact pads 194 may be insulated from each other by a first upper insulating film 193. The bit lines BL may be insulated from each other by a second upper insulating film 195. The bit line contact pads 194 and the bit lines BL may include metal, metal nitride, or a combination thereof. For example, the bit line contact pads 194 and the bit lines BL may include tungsten, titanium, tantalum, copper, aluminum, titanium nitride, tantalum nitride, tungsten nitride, or a combination thereof. Each of the first upper insulating film 193 and the second upper insulating film 195 may include a silicon oxide film, a silicon nitride film, or a combination thereof.

In the cell array structure CAS, a connection part insulating film 114 covering the conductive pad regions 112 may be between the common source line CSL and the intermediate insulating film. The connection part insulating film 114 may include a silicon oxide film, a silicon nitride film, or a combination thereof.

In the connection region CON, the contact structures CTS passing through the connection part insulating film 114 in the vertical direction (the Z direction) may be respectively on the conductive pad regions 112. An end portion of each of the contact structures CTS may be connected to one of a plurality of wiring layers ML between the contact structures CTS and the peripheral circuit structure PCS. The wiring layers ML may be at the same level as the bit lines BL and may pass through the second upper insulating film 195.

Each of the contact structures CTS may include a contact plug 116 extending lengthwise in the vertical direction (the Z direction). The sidewall of the contact plug 116 may be surrounded by an insulating plug 115. An opposite end of each of the contact structures CTS may be arranged to be electrically connected to one of the conductive pad regions 112.

The wiring structure MS may include a first upper wiring layer 172, a second upper wiring layer 174, and a third upper wiring layer 176. The wiring layer ML, the first upper wiring layer 172, the second upper wiring layer 174, and the third upper wiring layer 176 may include tungsten, titanium, tantalum, copper, aluminum, titanium nitride, tantalum nitride, tungsten nitride, or a combination thereof. In some example embodiments, the bit lines BL may include the same material as the wiring layer ML.

Each of the gate lines 130 may be connected to a plurality of circuits in a plurality of circuit regions of the peripheral circuit structure PCS through a conductive pad region 112, a contact structure CTS, a wiring structure MS, and a bonding structure BS.

In some example embodiments, a plurality of contact plugs 116 respectively included in a plurality of contact structures CTS and the first upper wiring layer 172, the second upper wiring layer 174, and the third upper wiring layer 176 of the wiring structure MS may include tungsten, titanium, tantalum, copper, aluminum, titanium nitride, tantalum nitride, tungsten nitride, or a combination thereof.

The transistors TR of the peripheral circuit structure PCS may include circuits, e.g., the row decoder 32, the page buffer 34, the data I/O circuit 36, the control logic 38, and the CSL driver 39. In some example embodiments, unit elements, such as a resistor and a capacitor, may be further arranged in the peripheral circuit structure PCS.

FIG. 18 is a cross-sectional view illustrating the inner crack detection structure ICDS according to some example embodiments.

According to some example embodiments, the inner crack detection structure ICDS may be formed by using a plurality of bonding structures BS including the first bonding metal pads 178 and the second bonding metal pads 278, which are described above with reference to FIG. 17. Referring to FIGS. 15 to 18, each of the bonding structures BS may be formed across the first semiconductor die 100A and the semiconductor die 100B, and the inner crack detection structure ICDS may include a portion of the first semiconductor die 100A and a portion of the second semiconductor die 100B. The inner crack detection structure ICDS may be arranged in a portion of the first semiconductor die 100A and a portion of the second semiconductor die 100B and thereby detect bonding failures between semiconductor dies.

In some example embodiments, any of the crack detecting structures (e.g., ICDS, OCDS, or CCDS) may determine whether a crack has occurred within a semiconductor die (e.g., first semiconductor die 100A or second semiconductor die 100B) or whether a bonding failure has occurred between adjacent semiconductor dies (e.g., between first semiconductor die 100A and second semiconductor die 100B) based on whether a test output signal TSO is detected in a path selection circuit (e.g., first path selection circuit PS1, second path selection circuit PS2, etc.) in response to a test input signal applied to any of the conducting segments (e.g., C1, I1, O1, etc.) of the crack detecting structures (e.g., ICDS, OCDS, or CCDS). Based on a result of the test output signal TSO, the semiconductor die may be scrapped or downgraded, leading to an improved yield and/or reliability and/or an earlier detection of inoperable parts and/or a decrease in fabrication time and/or costs.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

According to some example embodiments, because the inner crack detection structure ICDS includes at least a portion of each of the bonding structures BS in a bonding region of a wafer, a bonding failure between wafers may be detected using the inner crack detection structure ICDS.

According to various example embodiments, each of the outer crack detection structure OCDS, the inner crack detection structure ICDS, and the central crack detection structure CCDS may include a single layer, a plurality of single layers, or a plurality of stacked layers connected to each other in a semiconductor device.

While the inventive concepts have been particularly shown and described with reference to some example embodiments thereof, it will be understood that various changes in form and details may be made therein without departing from the spirit and scope of the following claims.

What is claimed is:

1. A semiconductor device comprising:
a semiconductor die including a central region and an outer region surrounding the central region;
a semiconductor integrated circuit across a plurality of sub regions of the central region;
an outer crack detection structure in the outer region along an edge of the outer region and divided into a plurality of outer conduction segments;
a central crack detection structure crossing the central region and divided into a plurality of central conduction segments;
a plurality of first path selection circuits each connected to at least one of the plurality of outer conduction segments and at least one of the plurality of central conduction segments; and
a second path selection circuit connected between the plurality of central conduction segments.

2. The semiconductor device of claim 1, wherein
each of the plurality of central conduction segments
has an end connected to one of the plurality of first path selection circuits and an opposite end connected to the second path selection circuit.

3. The semiconductor device of claim 1, wherein
the plurality of central conduction segments are electrically connected to each other through the plurality of first path selection circuits and the second path selection circuit and form a conduction loop.

4. The semiconductor device of claim 1, wherein
each of the plurality of outer conduction segments has an end connected to one of the plurality of first path selection circuits and an opposite end connected to another one of the plurality of first path selection circuits.

5. The semiconductor device of claim 1, wherein
the plurality of outer conduction segments are electrically connected to each other through the plurality of first path selection circuits and form a conduction loop.

6. The semiconductor device of claim 1, wherein
the plurality of first path selection circuits include a first selection circuit, a second selection circuit, a third selection circuit, and a fourth selection circuit,
the first selection circuit faces the third selection circuit in a first direction, and the second selection circuit faces the fourth selection circuit in a second direction that is perpendicular to the first direction.

7. The semiconductor device of claim 6, wherein
the second path selection circuit is at a center of the central region.

8. The semiconductor device of claim 1, further comprising
an inner crack detection structure in the central region along the edge of the outer region and divided into a plurality of inner conduction segments.

9. The semiconductor device of claim 8, wherein
the plurality of inner conduction segments are electrically connected to each other through the plurality of first path selection circuits and form a conduction loop.

10. The semiconductor device of claim 8, wherein
the plurality of first path selection circuits are configured to control electrical connection among the outer crack detection structure, the inner crack detection structure, and the central crack detection structure.

11. The semiconductor device of claim 8, wherein
each of the plurality of first path selection circuits is configured to output a signal input from one of one outer conduction segment among the plurality of outer conduction segments, one inner conduction segment among the plurality of inner conduction segments, and one central conduction segment among the plurality of central conduction segments to one of another outer conduction segment among the plurality of outer conduction segments, another inner conduction segment among the plurality of inner conduction segments, and another central conduction segment among the plurality of central conduction segments.

12. The semiconductor device of claim 1, wherein
each of the plurality of first path selection circuits and the second path selection circuit includes at least one selected from the group consisting of a switch, a multiplexer, a demultiplexer, or a tri-state buffer.

13. The semiconductor device of claim 8, wherein
the semiconductor die further includes a first semiconductor die and a second semiconductor die stacked on the first semiconductor die in a vertical direction, the first semiconductor die including a cell array structure, and the second semiconductor die including a peripheral circuit structure, and
the inner crack detection structure is across a portion of the first semiconductor die and a portion of the second semiconductor die.

14. A semiconductor device comprising:
a semiconductor die including a central region and an outer region surrounding the central region;
a semiconductor integrated circuit across a plurality of sub regions of the central region;
an outer crack detection structure in the outer region along an edge of the outer region and including a plurality of outer conduction segments;
a central crack detection structure crossing the central region in the central region and including a plurality of central conduction segments;
a plurality of first path selection circuits connected between the plurality of outer conduction segments and between the plurality of central conduction segments; and
a second path selection circuit connected between the plurality of central conduction segments.

15. The semiconductor device of claim 14, further comprising
an inner crack detection structure in the central region along the plurality of outer conduction segments and including a plurality of inner conduction segments.

16. The semiconductor device of claim 15, wherein
the plurality of inner conduction segments are respectively in the plurality of sub regions of the central region.

17. The semiconductor device of claim 15, wherein
the plurality of first path selection circuits is connected between the plurality of inner conduction segments.

18. The semiconductor device of claim 15, wherein
the plurality of first path selection circuits are configured to select and output one of signals respectively input from the outer crack detection structure, the inner crack detection structure, and the central crack detection structure.

19. A semiconductor device comprising:
a semiconductor die including a central region and an outer region surrounding the central region;
a semiconductor integrated circuit across a plurality of sub regions of the central region;
an outer crack detection structure in the outer region along an edge of the outer region and divided into a plurality of outer conduction segments;
an inner crack detection structure in the central region along the edge of the outer region and divided into a plurality of inner conduction segments;
a central crack detection structure crossing the central region and divided into a plurality of central conduction segments; and
a plurality of first path selection circuits each connected to at least one of the plurality of outer conduction segments, at least one of the plurality of inner conduction segments, and at least one of the plurality of central conduction segments.

20. The semiconductor device of claim 19, wherein
the plurality of first path selection circuits are configured to control electrical connection among the outer crack detection structure, the inner crack detection structure, and the central crack detection structure.
